(19) United States
(12) Patent Application Publication
(10) Pub. No.: US 2014/0042114 A1
(43) Pub. Date: Feb. 13, 2014

(54) ELECTRONIC DEVICE RACK

(71) Applicants: HON HAI PRECISION INDUSTRY CO., LTD., New Taipei (TW); HONG FU JIN PRECISION INDUSTRY (WuHan) CO., LTD., Wuhan (CN)

(72) Inventors: Yun-Lung CHEN, New Taipei (TW); Liang TU, Wuhan (CN)

(21) Appl. No.: 13/906,737

(22) Filed: May 31, 2013

(30) Foreign Application Priority Data
Aug. 7, 2012 (CN) 2012102783558

(51) Int. Cl. H05K 7/18

(52) U.S. Cl. CPC H05K 7/18
USPC 211/183

(57) ABSTRACT

An electronic device rack includes a first support leg, a second support leg substantially parallel to the first support leg, and a mounting member mounted between the first support leg and the second support leg. The first support leg defines a plurality of mounting holes. The mounting member includes member body, a first securing tab extending from the member body, and a protrusion extending from the member body. The first securing tab is engaged in one of the plurality of mounting holes to prevent the mounting member from moving along a first direction substantially perpendicular to the first support leg. The protrusion is engaged in one of the plurality of securing holes to prevent the mounting member from moving a third direction. The protrusion is used for being engaged into the one of the plurality of securing holes along the second direction.

### BACKGROUND

1. Technical Field

The present disclosure relates to an electronic device rack.

2. Description of Related Art

A vending machine generally includes a rack. The rack includes a plurality of support legs and a plurality of mounting members. A plurality of screws is screwed to the mounting members and support legs to secure them together by a tool, which is inefficient.

Therefore, there is room for improvement within the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an exploded, isometric view of an electronic device rack in accordance with one embodiment of the present disclosure.

FIG. 2 is similar to FIG. 1, but viewed from another aspect.

FIG. 3 is an isometric view of a mounting member of FIG. 1.

FIG. 4 is similar to FIG. 3, but viewed from another aspect.

FIG. 5 is an assembled view of FIG. 1.

FIG. 6 is a partial, enlarged view of FIG. 5.

FIG. 7 is another assembled view of FIG. 1.

FIG. 8 is a partial, enlarged view of FIG. 7.

FIG. 9 is another partial, enlarged view of FIG. 7.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean “at least one.”

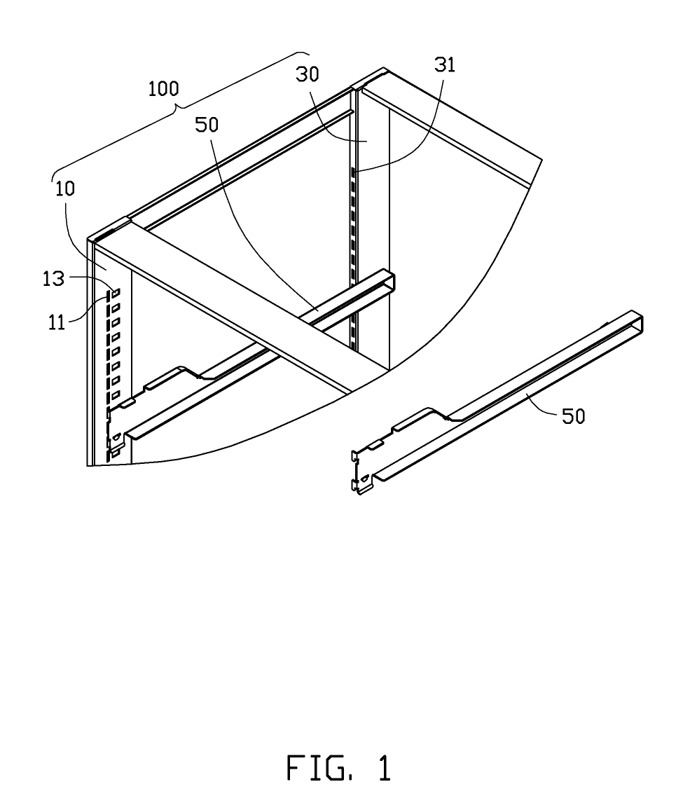

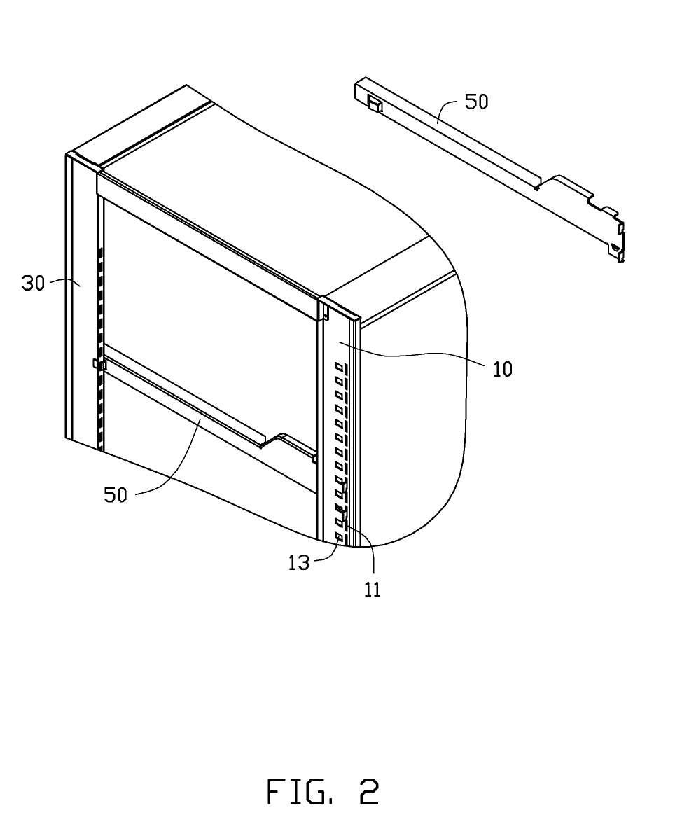

FIGS. 1 and 2, an electronic device rack includes two side frames 100. Each side frame 100 includes a first support leg 10, a second support leg 30, and a plurality of mounting members 50 mounted between the first support leg 10 and the second support leg 30. The two first support legs and the two second support legs are parallel to each other.

The first support leg 10 defines a plurality of mounting holes 11 and a plurality of securing holes 13. The mounting holes 11 and the securing holes 13 are both linearly arranged. Each mounting hole 11 is elongated. The arrangement direction of the mounting holes 11 is substantially parallel to the arrangement direction of the securing holes 13 and is substantially parallel to the second support leg 30. The second support leg 30 defines a plurality of inserting holes 31. The inserting holes 31 are linearly arranged. The arrangement direction of the inserting holes 31 is substantially parallel to the arrangement direction of the mounting holes 11. The inserting hole 31 is elongated.

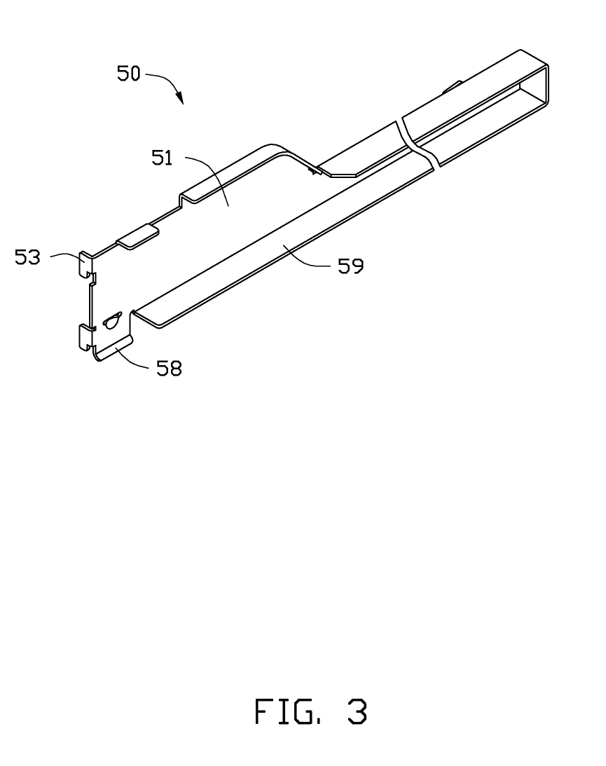

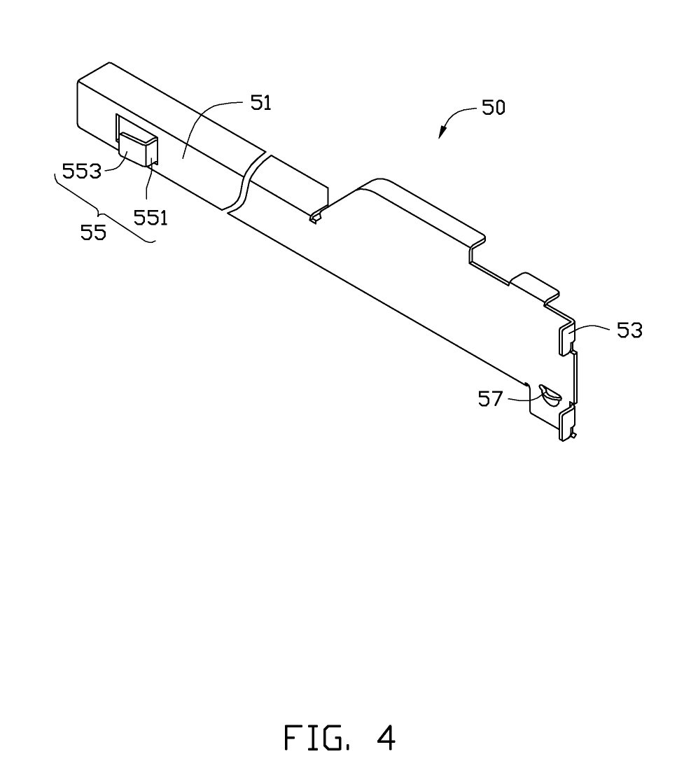

FIGS. 3 and 4 shows that each mounting member 50 includes a member body 51, two securing tabs 53 extending from the member body 51, and an inserting tab 55 extending from the member body 51. Each securing tab 53 is L-shaped and used for being engaged in the mounting hole 11. The inserting tab 55 is L-shaped and used for being inserted in the inserting hole 31. The inserting tab 55 includes a connecting portion 551 extending from the member body 51 and an inserting portion 553 perpendicularly extending from the connecting portion 551. The mounting member 50 further includes a protrusion 57, extending from the member body 51, and an inclining portion 58, extending inward on a slant from the member body 51. The inclining portion 58 is used for preventing the securing tabs 53 from resisting the first support leg 10, when the securing tabs 53 are engaged into the mounting holes 11. The mounting members 50 further includes a sliding portion 59 inward and perpendicularly extending from the member body 51. The protrusion 57 is used for being engaged in the securing hole 13.

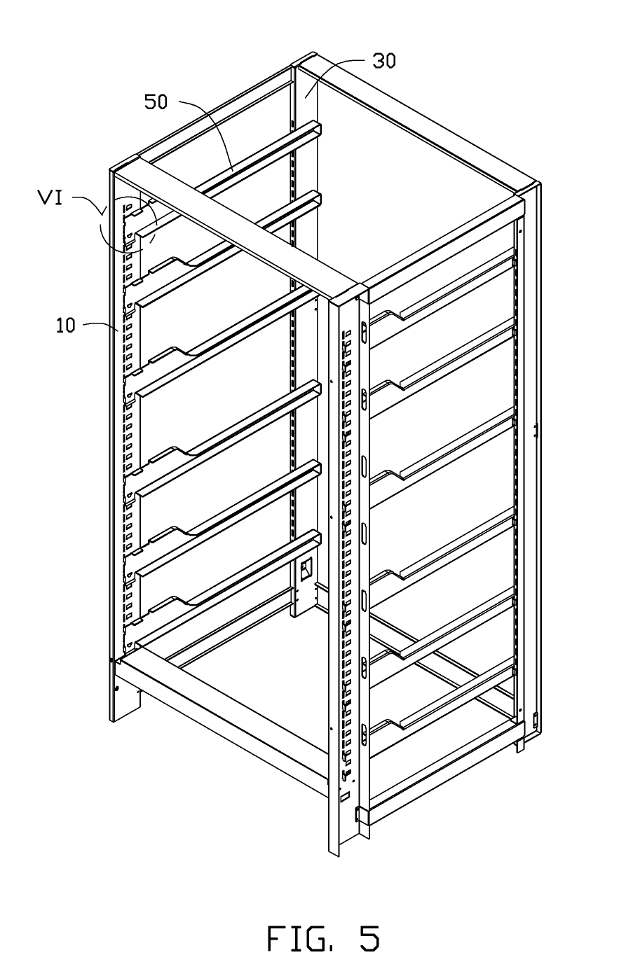

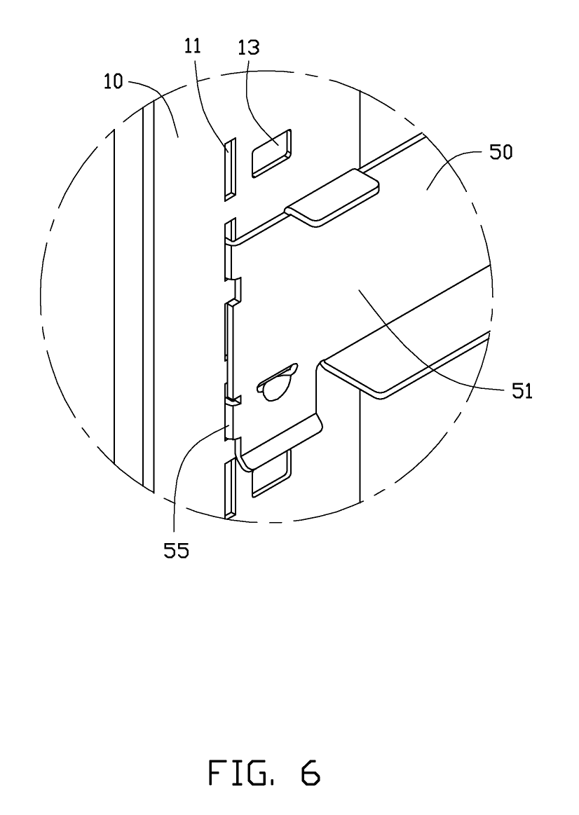

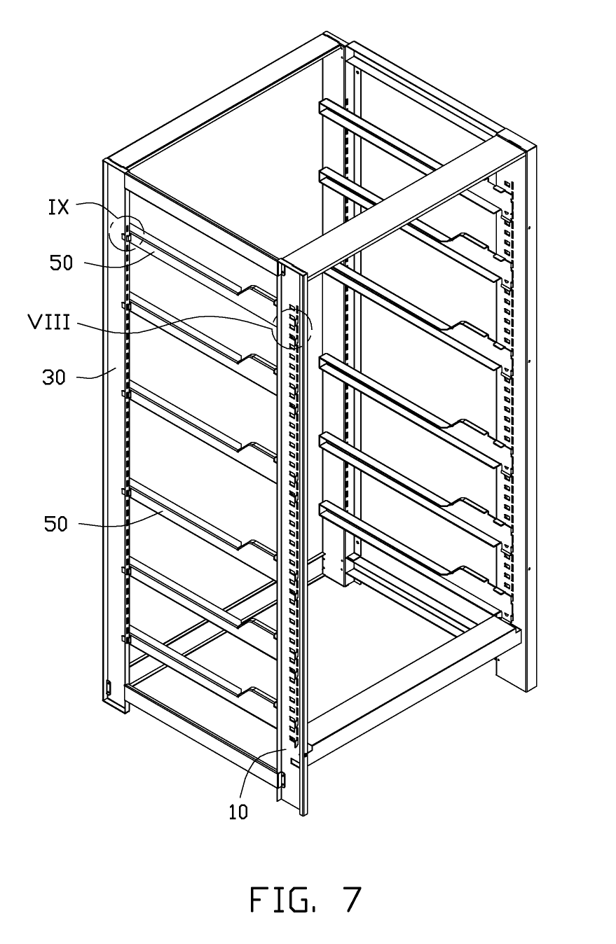

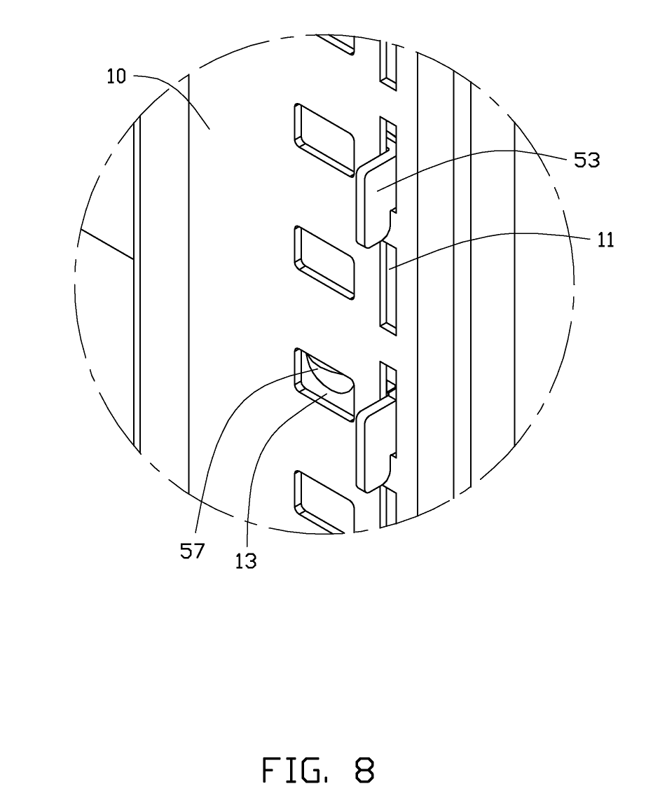

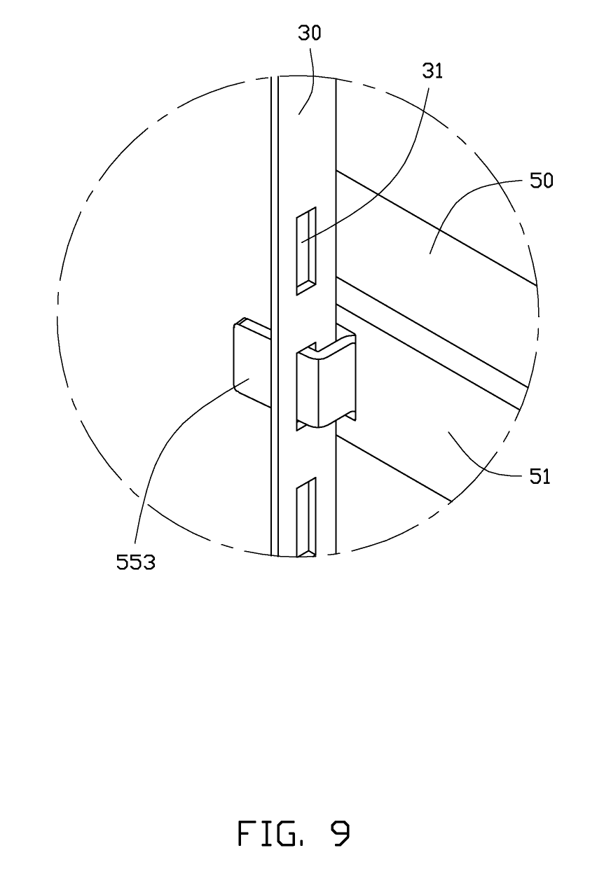

FIGS. 5 to 9 show that in assembly, the inserting tab 55 of the mounting member 50 corresponds to the inserting holes 31 of the second support legs 30. The mounting member 50 moves to the second support legs 30 to enable the inserting tab 55 to be inserted into the corresponding inserting hole 31. The two securing tabs 53 of the mounting member 50 pass through the two mounting holes 11 and moves downward along a first direction, substantially parallel to the first support leg 10. At this time, the protrusion 57 of the mounting member 50 resists the first support leg 10 to enable the member body 51 of the mounting member 50 to be deformed. The mounting member 50 keeps on moving until the protrusion 57 is aligned with the securing hole 13. The member body 51 rebounds to enable the protrusion 57 to engage in the securing hole 13, thereby preventing the mounting member 50 from moving a second direction that is substantially opposite to the first direction. At this time, the securing tabs 53 engage the edge of the mounting holes 11 for preventing the mounting member 50 from moving in a third direction, that is substantially perpendicular to the first support leg 10, and for preventing the mounting member 50 from moving along the first direction. The two side frames 100 and the sliding portion 59 of the mounting member 50 are on the same plane.

It is to be understood, however, that even though numerous characteristics and advantages of the embodiments have been set forth in the foregoing description, together with details of the structure and functions of the embodiments, the disclosure is illustrative only, and changes may be made in detail, especially in the matters of shape, size, and arrangement of parts within the principles of the present disclosure to the full extent indicated by the broad general meaning of the terms in which the appended claims are expressed.

What is claimed is:

1. An electronic device rack, comprising:
a first support leg, the first support leg defines a plurality of mounting holes arranged in a first line and a plurality of securing holes arranged in a second line, that is substantially parallel to the first line;
a second support leg substantially parallel to the first support leg and the first line; and
a mounting member mounted between the first support leg and the second support leg; the mounting member comprises a member body, a first securing tab extending from the member body, and a protrusion extending from the member body; the first securing tab is engaged in one of the plurality of mounting holes to prevent the mounting member from moving along a first direction that is substantially perpendicular to the first support leg and along a second direction that is substantially parallel to the first support leg; the protrusion is engaged in one of the plurality of securing holes to prevent the mounting member from moving a third direction that is substantially opposite to the second direction; and the protrusion is configured to be engaged into the one of the plurality of securing holes along the second direction.

2. The electronic device rack of claim 1, wherein the mounting member further comprises an inserting tab extending from the member body; the second support leg defines a plurality of inserting holes arranged in a third line; the third line is substantially parallel to the first line; and the inserting tab is located in one of the plurality of inserting holes.

3. The electronic device rack of claim 2, wherein the inserting tab is L-shaped; the inserting tab comprises a connecting portion, extending from the member body, and inserting portion, extending from the connecting portion; and the inserting portion is inserted in the one of the plurality of inserting holes.

4. The electronic device rack of claim 3, wherein the one of the plurality of inserting holes is elongated.

5. The electronic device rack of claim 1, wherein the mounting member further comprises a second securing tab extending from the member body, and the second securing tab is engaged in another one of the plurality of mounting holes.

6. The electronic device rack of claim 1, wherein the first securing tab is L-shaped.

7. The electronic device rack of claim 1, wherein the mounting member further comprises an inclining portion inwardly extending from the member body, and the inclining portion is configured to prevent the first securing tab from resisting the first support leg when the first securing tab is engaged into the one of the plurality of mounting holes.

8. The electronic device rack of claim 1, wherein the mounting member further comprises a sliding portion inward extending from the member body.

9. The electronic device rack of claim 1, wherein the one of the plurality of mounting holes is elongated.

10. A electronic device rack, comprising:
a first support leg, the first support leg defines a first mounting hole;
a second support leg substantially parallel to the first support leg, the second support leg defines an inserting hole; and
a mounting member mounted between the first support leg and the second support leg, the mounting member comprises a member body, a first securing tab extending from the member body, and an inserting tab extending from the member body; the inserting tab is located in the inserting hole; and the first securing tab is engaged in the first mounting hole to prevent the mounting member from moving along a first direction that is substantially perpendicular to the first support leg and along a second direction that is substantially parallel to the first support leg.

11. The electronic device rack of claim 10, wherein the first support leg further defines a securing hole; the mounting member further comprises a protrusion extending from the member body; the protrusion is engaged in the securing hole to prevent the mounting member from moving a third direction that is substantially opposite to the second direction; and the protrusion is configured to be engaged into the securing hole along the second direction.

12. The electronic device rack of claim 10, wherein the inserting tab is L-shaped; the inserting tab comprises a connecting portion extending from the member body and inserting portion extending from the connecting portion; and the inserting portion is inserted in the inserting hole.

13. The electronic device rack of claim 10, wherein the inserting hole is elongated.

14. The electronic device rack of claim 10, wherein the first support leg defines a second mounting hole; the mounting member further comprises a second securing tab extending from the member body, and the second securing tab is engaged in the second mounting hole.

15. The electronic device rack of claim 10, wherein the first securing tab is L-shaped.

16. The electronic device rack of claim 10, wherein the mounting member further comprises an inclining portion inwardly extending from the member body, and the inclining portion is configured to prevent the first securing tab from resisting the first support leg when the first securing tab is engaged into the first mounting hole.

17. The electronic device rack of claim 10, wherein the mounting member further comprises a sliding portion inward extending from the member body.

18. The electronic device rack of claim 10, wherein the first mounting hole is elongated.
